(19) United States
(12) Patent Application Publication
(10) Pub. No.: US 2023/0198521 A1
(43) Pub. Date: Jun. 22, 2023

(54) Wireless Voltage link

(71) Applicant: Kay C. Robinson, JR., Detroit, MI (US)

(72) Inventor: Kay C. Robinson, JR., Detroit, MI (US)

(21) Appl. No.: 17/803,675

(22) Filed: Oct. 7, 2022

Related U.S. Application Data
(63) Continuation-in-part of application No. 17/502,250, filed on Oct. 15, 2021.

(51) Int. Cl. H03K 17/72

(52) U.S. Cl. CPC H03K 17/72

(57) ABSTRACT

The wireless voltage link uses a coil to induce voltage onto a transistor. By controlling the amount of the current that flows through the coil, one is able to control the strength of the magnetic field emitted by the inductor. And by controlling the q-point of the transistor, the amount voltage and current induced, the transistor can then be used as a switch or an amplifier without any electrical/electronic connection to the internal coil. The use of a transistor enables high speed switching and potential amplification of communication signals.

### BACKGROUND OF THE INVENTION

The original purpose of the invention was to create a relay with the ability to operate at high speeds. Relays use electromagnetism to operate a mechanical switch. This causes, what's referred, a contact bounce or debouncing effect. Because of the mechanical switch, the speeds or frequencies at which the relay can operate are limited. By replacing the mechanical switch with an electronic one the operating potential of the relay increases.

### SUMMARY OF THE INVENTION

Using the same principal of how the relay operates, an electromagnet to and transfer energy, and replacing the mechanical switch with an electronic one, transistor or thyristor, the operating potential of the relay as well as it's potential uses increases significantly. Also depending on how the transistor is biased it can even be used as an amplifier. Electric power and electronic communication can be transferred from the coil to the transistor without any electrical/electronic connection.

### BRIEF DESCRIPTION OF THE DRAWINGS

FIG. 1 is a inductor in a same housing as a Bipolar Junction Transistor (BJT).

FIG. 2 is a inductor in a same housing as a Uni-Junction transistor (UJT).

FIG. 3 is a inductor in a same housing as a Programmable Unijunction Transistor (PUT).

FIG. 4 is a inductor in a same housing as a Silicon Controlled Rectifier (SCR) thyristor.

FIG. 5 is a inductor in a same housing as a Gate Turn-Off (GTO) thyristor.

FIG. 6 is a inductor in a same housing as an Insulated Gate Bipolar Transistor (IGBT).

FIG. 7 is a circuit drawing describing the operation of invention using a BJT.

FIG. 8 is a circuit drawing describing the operation of invention using a UJT.

FIG. 9 is a circuit drawing describing the operation of invention using a PUT.

FIG. 10 is a circuit drawing describing the operation of invention using a SCR thyristor.

FIG. 11 is a circuit drawing describing the operation of invention using a GTO thyristor.

FIG. 12 is a circuit drawing describing the operation of invention using a IGBT.

### DETAILED DESCRIPTION

FIG. 1 uses a inductor in a same housing as a BJT. When an electrical current passes through the inductor and is energized, an electromagnetic field will develop and induce a voltage onto the base of the transistor. Depending on the q-point of the internal BJT the induced voltage as well as current will be amplified, or the transistor will act as a switch moving between saturation cutoff modes. The result is the voltage applied to the internal inductor will be induced onto the internal BJT without any electrical/electronic connection between the inductor and the BJT. The apparatus encompassing this invention is applicable to all BJT's.

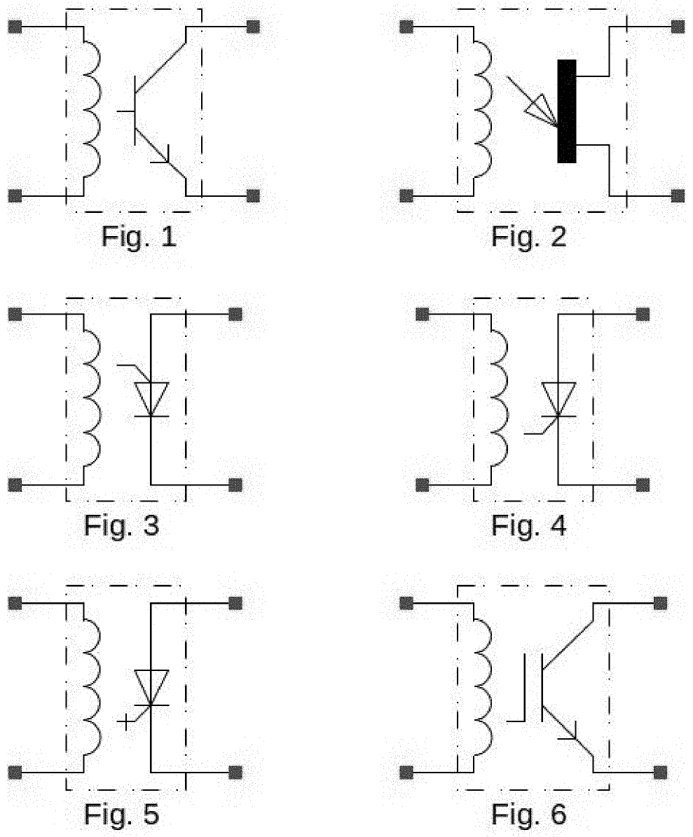

FIG. 2 uses a inductor in a same housing as a UJT. When an electrical current passes through the internal inductor of the electromagnetic coupler and is energized, an electromagnetic field will develop and induce a voltage onto the emitter of the transistor. The electromagnetic coupler utilizing an internal UJT is not meant to be used as an amplifying device but as a voltage controlled switch and will have no electrical/electronic connection to the internal inductor.

FIG. 3 uses a inductor in a same housing as a PUT. When an electrical current passes through the inductor and is energized, an electromagnetic filed will develop and induce a voltage onto the gate of the transistor. The electromagnetic coupler in FIG. 4 utilizing an internal PUT will act electromagnetic coupler in FIG. 3 except that the peak voltage in FIG. 4 can be controlled. The voltage induced will be accomplished without any electrical/electronic connection between the internal inductor and the internal PUT.

FIG. 4 uses a inductor in a same housing as a SCR thyristor. When an electrical current passes through the inductor and is energized, an electromagnetic field will develop and induce a voltage onto the gate of the thyristor. The internal SCR thyristor must biased like a diode. The internal SCR of the electromagnetic coupler will not conduct until a positive voltage is induced onto its gate with, respect to it's cathode, by the inductor and will only conduct in one direction. The internal inductor will not have any electrical/electronic connection to the internal SCR thyristor.

FIG. 5 uses a inductor in a same housing as a GTO thyristor. When an electrical current passes through the inductor and is energized an electromagnetic field will develop and induce a voltage onto the gate of the thyristor. The electromagnetic coupler utilizing an internal GTO can be controlled with a positive voltage, relative to its cathode, to activate and negative voltage to deactivate induced onto the gate of the internal GTO. The internal inductor will not have any electrical/electronic connection to the internal GTO thyristor.

FIG. 6 uses a inductor in a same housing as an IGBT. When an electrical current passes through the inductor and is energized, an electromagnetic field will develop and induce a voltage onto the gate of the transistor. Depending on the q-point of the internal IGBT the induced voltage as well as current will be amplified, or the transistor will act as a switch moving between saturation cutoff modes. The result is the voltage applied to the internal inductor will be induced onto the internal IGBT without any electrical/electronic connection between the inductor and the IGBT. The apparatus encompassing this invention is applicable to all IGBT's.

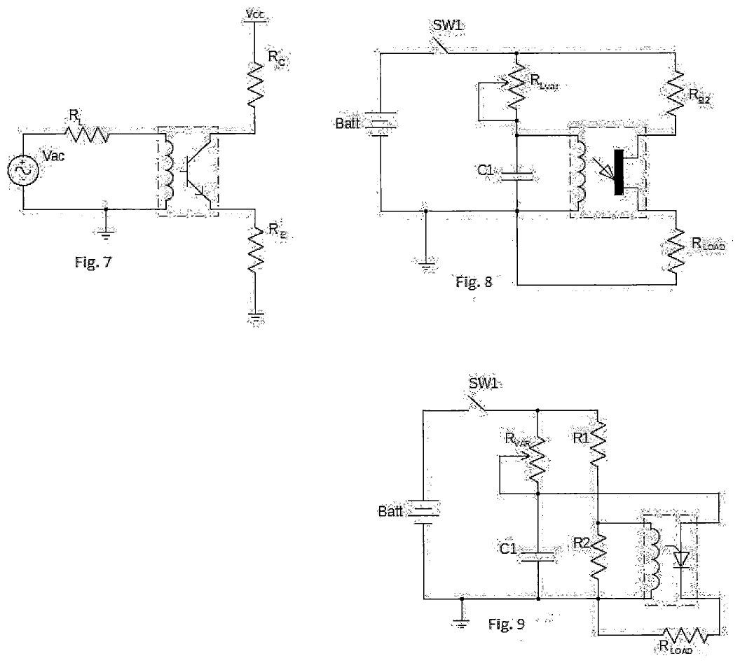

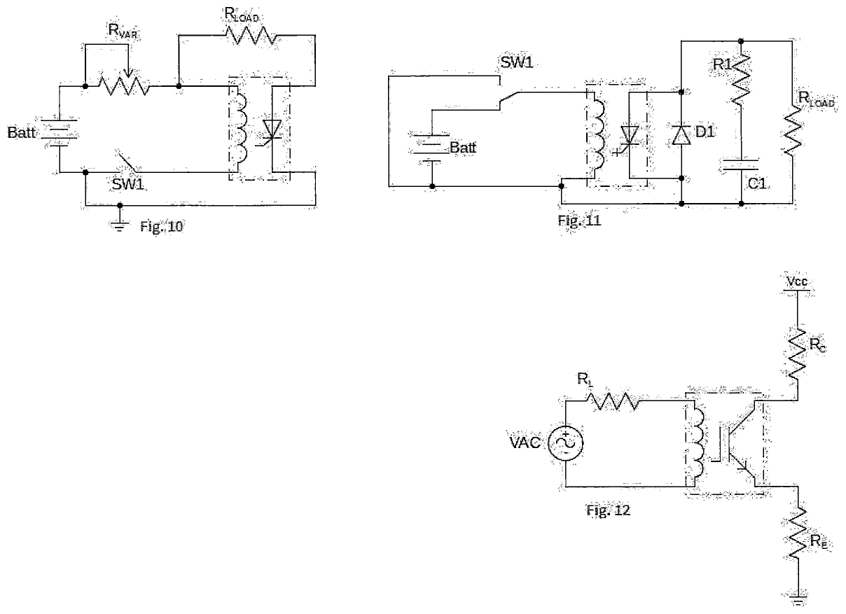

FIG. 7 is an example of one of the potential applications of the electromagnetic coupler, utilizing an internal BJT, and is also brief visual description of the operation of the invention. FIG. 9 uses a regular DC power source to power the internal BJT of the electromagnetic coupler. The AC power source is a representation of an electronic communication source or signal. The R_{C} and R_{E} resistors are used to set the saturation current of the BJT. R_{L} is used to control the current through the inductor and thereby the amount of current induced onto the base of the BJT while maintaining no electrical/electronic connection between the internal inductor and the internal BJT.

FIG. 8 is an example of one the potential applications of the electromagnetic coupler, utilizing an internal UJT, and is also a brief visual description of the operation of the invention. FIG. 11 is an illustration of a relaxation oscillator circuit. When SW1, the switch, closes C1, the capacitor, charges by the variable resistor, R_{LVAR}. When the voltage across C1 reaches the UJT's peak value, the needed voltage will then be induced by the internal inductor onto the emitter of the internal UJT. The internal UJT will turn on and conduct current driving R_{LOAD}, the load, while maintaining no electrical/electronic connection to the internal inductor.

FIG. 9 is an example of one of the potential applications of the electromagnetic coupler, utilizing an internal PUT, and is also a brief visual description of the invention. FIG. 12 is an illustration of a relaxation oscillator circuit. When SW1, the switch, closes C1, the capacitor, charges by means R_{LVAR}, the variable resistor. When the internal PUT's anode to cathode exceeds induced gate by 0.7 volts C1, the capacitor, will discharge through the internal PUT and drive R_{LOAD}, the load. The gate to cathode voltage to be induced, overcome by C1, and activate the internal PUT will be set using a small voltage divider network of R1 and R2, to energize the internal inductor and induce a trigger voltage onto the internal PUT of the electromagnetic coupler. The PUT will turn on and conduct current driving the load while maintaining no electrical/electronic connection between the internal inductor and the internal PUT.

FIG. 10 is an example of one of the potential applications of the electromagnetic coupler, utilizing an internal SCR thyristor, and is also a brief description of the operation of the invention. FIG. 13 uses a battery to power the circuit, however the internal SCR of the electromagnetic coupler will not conduct and power R_{LOAD}, the load, until it's required gate voltage is met. When SW1, the switch, closes the internal inductor of the electromagnetic coupler will energize and induce the required voltage onto the gate of the internal SCR thyristor, turning it on causing it to conduct and drive R_{L}, the load, while maintaining no electrical/electronic connection between the internal inductor and the SCR thyristor.

FIG. 11 is an example of one of potential applications of the electromagnetic coupler, utilizing an internal GTO thyristor, and is also a brief visual description of the operation of the invention. FIG. 15 is a basic drive circuit with the electromagnetic coupler utilizing an internal GTO thyristor. When SW1, the switch, is connected to the positive contact it will energize the internal inductor of the electromagnetic coupler which will then induce a positive voltage onto the gate of the internal GTO of the electromagnetic coupler, turning it on and causing it to conduct. The voltage will then be rectified by D1, the diode, and filtered by C1, the capacitor. When SW1 is connected to the negative contact it will energize the internal inductor of the electromagnetic coupler which will then induce a negative voltage onto the gate of the internal GTO turning it off and stopping it from conducting while maintaining no electrical/electronic connection between the internal inductor and the internal GTO thyristor.

FIG. 12 is an example of one of the potential applications of the electromagnetic coupler, utilizing an internal IGBT, and is also brief visual description of the operation of the invention. FIG. 16 uses a regular DC power source to power the internal IGBT of the electromagnetic coupler. The AC power source is a representation of an electronic communication source or signal. The R_{C} and R_{E} resistors are used to set the saturation current of the IGBT. R_{L} is used to control the current through the inductor and thereby the amount of current induced onto the base of the IGBT while maintaining no electrical/electronic connection between the internal inductor and the internal IGBT.

I claim:

1. An electronic component comprising:
a) a housing which consists of an inductor and a transistor; wherein said inductor transfers electrical energy through electromagnetic induction onto a control terminal of the transistor within the same housing

2. The electronic component of claim 1, wherein the transistor is a bipolar junction transistor (BJT).

3. (canceled)

4. The electronic component of claim 1, wherein the transistor is a unijunction transistor (UJT).

5. The electronic component of claim 1, wherein the transistor is a programmable unijunction transistor (PUT).

6. The electronic component of claim 1, wherein the transistor is an insulated gate bipolar transistor (IGBT).

7. An electronic component comprising:
a) a housing which consists of an inductor and a thyristor; wherein said inductor transfers electrical energy through electromagnetic induction onto a control terminal of the thyristor within the same housing

8. The electronic component of claim 6, wherein the thyristor is a silicon-controlled rectifier (SCR).

9. The electronic component of claim 6, wherein the thyristor is a gate turn off thyristor (GTO).

10. (canceled)
